(19) United States
(12) Patent Application Publication
(10) Pub. No.: US 2019/0035899 A1
(43) Pub. Date: Jan. 31, 2019

(54) Semiconductor Device and Method for Manufacturing the Semiconductor Device

(71) Applicant: Sanken Electric Co., Ltd., Saitama (JP)

(72) Inventors: Hiroko KAWAGUCHI, Saitama (JP); Hiroshi SHIKAUCHI, Saitama (JP); Hiromichi KUMAKURA, Saitama (JP); Shinji KUDOH, Saitama (JP); Yuki TANAKA, Saitama (JP)

(21) Appl. No.: 15/662,453

(22) Filed: Jul. 28, 2017

(51) Int. Cl. H01L 29/36; H01L 29/06; H01L 29/16; H01L 29/165; H01L 29/66; H01L 29/872; H01L 29/47; H01L 29/861

(52) U.S. Cl. CPC H01L 29/36; H01L 29/0619; H01L 29/1608; H01L 29/165; H01L 29/861; H01L 29/872; H01L 29/47; H01L 29/66068; H01L 29/66143

(57) ABSTRACT

A semiconductor device and a method for manufacturing the semiconductor device. The semiconductor device includes a middle region which is configured between an upper region and a lower region; a doping concentration of a first conductivity type in the middle region is lower than the doping concentration of the first conductivity type in a drift layer. Therefore, a depletion layer may be extended and connected to the lower region when a backward biasing voltage is applied; an electric field of the upper region may be reduced.

### TECHNICAL FIELD

Embodiments of the present disclosure generally relate to the field of semiconductors, and more particularly, to a semiconductor device and a method for manufacturing the semiconductor device.

### BACKGROUND

A semiconductor device (or may be referred to as a semiconductor element, component, apparatus, and so on) may include a substrate, a drift layer and an electrode layer. For example, materials mainly used in the substrate and the drift layer may be silicon carbide (Sic). Furthermore, some regions may be buried within the drift layer.

FIG. 1 is a diagram which shows an example of a semiconductor device in the prior art. As shown in FIG. 1, a semiconductor device 100 may include a silicon carbide drift layer 101 which has a first conductivity type (such as n-type, or may be referred to as n-doping), a silicon carbide substrate 102 which has the first conductivity type and an electrode layer 103 which is configured on the silicon carbide drift layer 101.

As shown in FIG. 1, a contact surface 1011 is formed in a first direction (such as X direction in FIG. 1) between the silicon carbide drift layer 101 and the electrode layer 103. The semiconductor device 100 may further include an upper region (or may be referred to as a surface region) 104 which has a second conductivity type (such as p-type, or may be referred to as p-doping); the upper region 104 is configured within the silicon carbide drift layer 101 and contacts (or is connected to) the contact surface 1011.

As shown in FIG. 1, the semiconductor device 100 may further include a lower region (or may be referred to as a buried region) 105 which has the second conductivity type; the lower region 105 is configured within the silicon carbide drift layer 101 and under the upper region 104 in a second direction (such as Y direction in FIG. 1) which is substantially orthogonal to the first direction.

As shown in FIG. 1, the semiconductor device 100 may further include a neighboring region 106 which has the first conductivity type; the neighboring region 106 is configured within the silicon carbide drift layer 101 and is adjacent to the upper region 104.

This section introduces aspects that may facilitate a better understanding of the disclosure. Accordingly, the statements of this section are to be read in this light and are not to be understood as admissions about what is in the prior art or what is not in the prior art.

### SUMMARY

However, it was found by the inventor that a depletion layer is difficult to expand around the lower region 105 as compared with the upper region 104 when a backward biasing voltage is applied. Therefore, an electric field of the upper region 104 is still high; a breakdown behavior and a long-term reliability of the semiconductor device need to be further improved.

In order to solve at least part of the above problems, methods, apparatus, devices are provided in the present disclosure. Features and advantages of embodiments of the present disclosure will also be understood from the following description of specific embodiments when read in conjunction with the accompanying drawings, which illustrate, by way of example, the principles of embodiments of the present disclosure.

In general, embodiments of the present disclosure provide a semiconductor device and a method for manufacturing the semiconductor device.

In a first aspect, a semiconductor device is provided. The semiconductor device includes a drift layer having a first conductivity type; an electrode layer configured on the drift layer, a contact surface being formed in a first direction between the drift layer and the electrode layer; a first region having a second conductivity type, the first region being configured within the drift layer and contacting the contact surface; a second region having the first conductivity type, the second region being configured within the drift layer and connected to the first region in a second direction which is orthogonal to the first direction, a doping concentration of the first conductivity type in the second region being lower than the doping concentration of the first conductivity type in the drift layer; and a third region having the second conductivity type, the third region being configured within the drift layer and connected to the second region in the second direction.

In one embodiment, the semiconductor device further includes a fourth region having the first conductivity type, the fourth region being configured within the drift layer and being adjacent to the first region, the doping concentration of the first conductivity type in the fourth region being higher than the doping concentration of the first conductivity type in the drift layer.

In one embodiment, the semiconductor device further includes a substrate having the first conductivity type, the drift layer being configured on the substrate, the doping concentration of the first conductivity type in the drift layer being lower than the doping concentration of the first conductivity type in the substrate.

In one embodiment, the first conductivity type is n-doping and the second conductivity type is p-doping.

In one embodiment, a plurality of the first regions are configured within the drift layer and arranged along the contact surface.

In one embodiment, corresponding to the first region, a plurality of the second regions and/or the third regions are configured within the drift layer.

In one embodiment, as distances from the contact surface in the second direction are increased, widths of the second regions and/or the third regions are decreased.

In one embodiment, as distances from the contact surface in the second direction are increased, the doping concentration of the first conductivity type in the second regions and/or the doping concentration of the second conductivity type in the third regions is decreased.

In one embodiment, the second region and the third region are alternatively configured along the second direction.

In one embodiment, a surface of the fourth region towards (or facing) the drift layer is configured to enlarge a contact area which is formed between the fourth region and the drift layer.

In one embodiment, a cross-section of the fourth region comprises one of the following shapes: a triangle shape, a ladder shape and a curved shape.

In a second aspect, a method for manufacturing a semiconductor device is provided. The method includes providing a drift layer which has a first conductivity type; providing an electrode layer which is configured on the drift layer, a contact surface being formed in a first direction between the drift layer and the electrode layer; providing a first region which has a second conductivity type, the first region being configured within the drift layer and contacted to the contact surface; providing a second region which has the first conductivity type, the second region being configured within the drift layer and connected to the first region in a second direction which is orthogonal to the first direction, a doping concentration of the first conductivity type in the second region being lower than the doping concentration of the first conductivity type in the drift layer; and providing a third region which has the second conductivity type, the third region being configured within the drift layer and connected to the second region in the second.

In one embodiment, the method further includes providing a fourth region which has the first conductivity type, the fourth region being configured within the drift layer and being adjacent to the first region, the doping concentration of the first conductivity type in the fourth region being higher than the doping concentration of the first conductivity type in the drift layer.

In one embodiment, the method further includes providing a substrate which has the first conductivity type, the drift layer being configured on the substrate and the doping concentration of the first conductivity type in the drift layer being lower than the doping concentration of the first conductivity type in the substrate.

According to various embodiments of the present disclosure, a middle region (the second region) having the first conductivity type is configured between the upper region (the first region) and the lower region (the third region), and a doping concentration of the first conductivity type in the second region is lower than the doping concentration of the first conductivity type in the drift layer.

Therefore, the depletion layer may be extended and connected to the lower region when the backward biasing voltage is applied. An electric field of the upper region may be reduced; a breakdown behavior and a long-term reliability of the semiconductor device may be further improved.

### BRIEF DESCRIPTION OF THE DRAWINGS

The above and other aspects, features, and benefits of various embodiments of the disclosure will become more fully apparent, by way of example, from the following detailed description with reference to the accompanying drawings, in which like reference numerals or letters are used to designate like or equivalent elements. The drawings are illustrated for facilitating better understanding of the embodiments of the disclosure and not necessarily drawn to scale, in which:

FIG. 1 is a diagram which shows an example of a semiconductor device in the prior art;

FIG. 2 is a diagram which shows an example of forming a depletion layer;

FIG. 3 is a diagram which shows a schematic illustration of a cross-section of a semiconductor device 300 in accordance with an embodiment of the present disclosure;

FIG. 4 is a diagram which shows a schematic illustration of a cross-section of a semiconductor device 400 in accordance with an embodiment of the present disclosure;

FIG. 5 is a diagram which shows an example of forming a depletion layer in accordance with an embodiment of the present disclosure;

FIG. 6 is a diagram which shows a schematic illustration of a cross-section of a semiconductor device 600 in accordance with an embodiment of the present disclosure;

FIG. 7 is a diagram which shows a schematic illustration of a cross-section of a semiconductor device 700 in accordance with an embodiment of the present disclosure;

FIG. 8 is a diagram which shows a schematic illustration of a cross-section of a semiconductor device 800 in accordance with an embodiment of the present disclosure;

FIG. 9 is a diagram which shows a schematic illustration of a cross-section of a semiconductor device 900 in accordance with an embodiment of the present disclosure;

FIG. 10 is a diagram which shows a method 1000 for manufacturing a semiconductor device in accordance with an embodiment of the present disclosure.

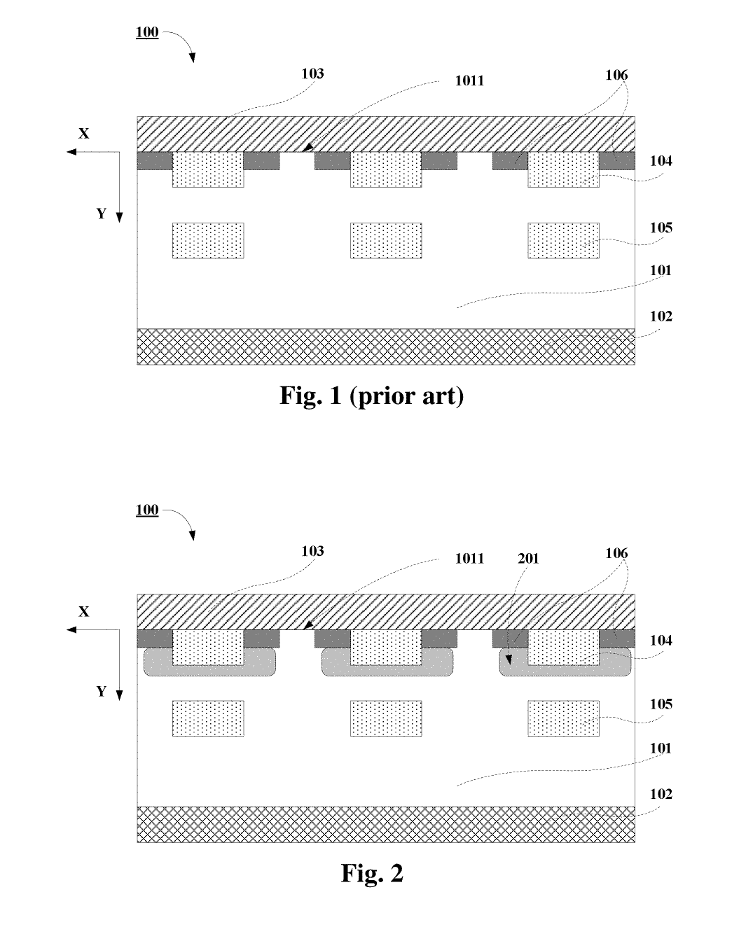

### DETAILED DESCRIPTION

The present disclosure will now be described with reference to several example embodiments. It should be understood that these embodiments are discussed only for the purpose of enabling those skilled persons in the art to better understand and thus implement the present disclosure, rather than suggesting any limitations on the scope of the present disclosure.

It should be understood that when an element is referred to as being “connected” or “coupled” or “contacted” to another element, it may be directly connected or coupled or contacted to the other element or intervening elements may be present. In contrast, when an element is referred to as being “directly connected” or “directly coupled” or “directly contacted” to another element, there are no intervening elements present. Other words used to describe the relationship between elements should be interpreted in a like fashion (e.g., “between” versus “directly between”, “adjacent” versus “directly adjacent”, etc.).

As used herein, the terms “first” and “second” refer to different elements. The singular forms “a” and “an” are intended to include the plural forms as well, unless the context clearly indicates otherwise. The terms “comprises,” “comprising,” “has,” “having,” “includes” and/or “including” as used herein, specify the presence of stated features, elements, and/or components and the like, but do not preclude the presence or addition of one or more other features, elements, components and/or combinations thereof.

The term “based on” is to be read as “based at least in part on”. The term “cover” is to be read as “at least in part cover”. The term “one embodiment” and “an embodiment” are to be read as “at least one embodiment”. The term “another embodiment” is to be read as “at least one other embodiment”. Other definitions, explicit and implicit, may be included below.

In this disclosure, unless otherwise defined, all terms (including technical and scientific terms) used herein have the same meaning as commonly understood by one of ordinary skill in the art to which example embodiments belong. It will be further understood that terms, e.g., those defined in commonly used dictionaries, should be interpreted as having a meaning that is consistent with their meaning in the context of the relevant art and will not be interpreted in an idealized or overly formal sense unless expressly so defined herein.

FIG. 2 is a diagram which shows an example of forming a depletion layer. As shown in FIG. 2, a depletion layer 201 is difficult to expand around the lower region 105 as compared with the upper region 104 when a backward biasing voltage is applied. Therefore, an electric field of the upper region 104 is still high; a breakdown behavior and a long-term reliability of the semiconductor device need to be further improved.

### A First Aspect of Embodiments

A semiconductor device is provided in those embodiments.

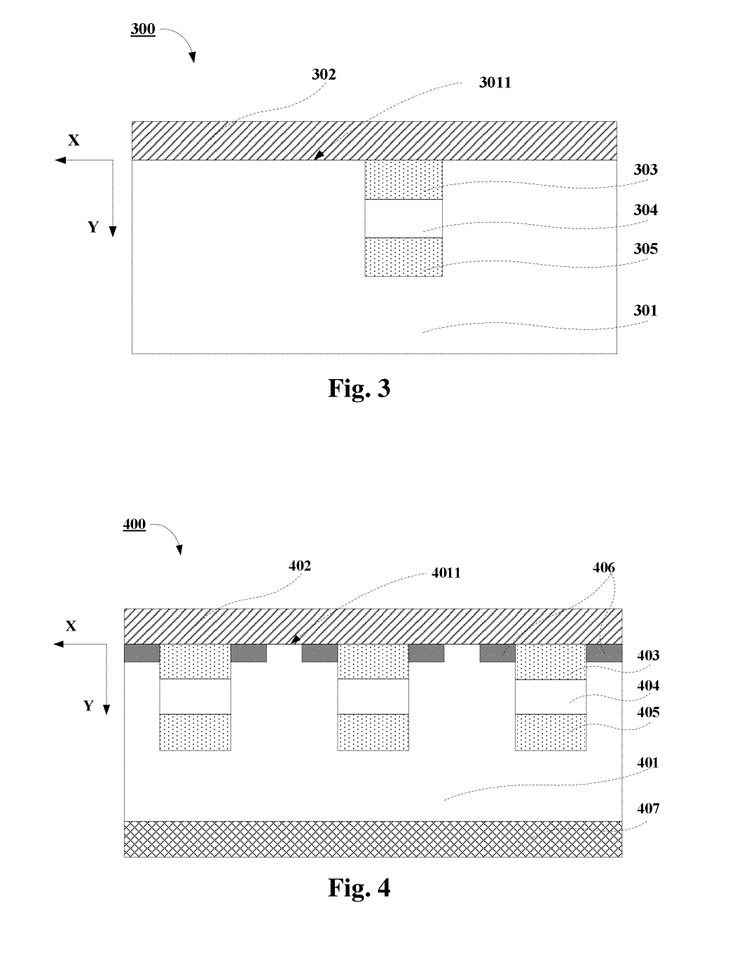

FIG. 3 is a diagram which shows a schematic illustration of a cross-section of a semiconductor device 300 in accordance with an embodiment of the present disclosure. As shown in FIG. 3, the semiconductor device 300 includes a drift layer 301 which has a first conductivity type (such as n-type, or may be referred to as n-doping) and an electrode layer 302 which is configured on the drift layer 301.

As shown in FIG. 3, a contact surface 3011 is formed in a first direction (such as X direction) between the drift layer 301 and the electrode layer 302. The semiconductor device 300 may further include a first region (or may be referred to as an upper region or a surface region) 303 which has a second conductivity type (such as p-type, or may be referred to as p-doping); the first region 303 is configured within the drift layer 301 and is contacted to the contact surface 3011.

As shown in FIG. 3, the semiconductor device 300 may further include a second region (or may be referred to as a middle region) 304 which has the first conductivity type; the second region 304 is configured within the drift layer 301 and is connected to the first region 303 in a second direction (such as Y direction) which is basically orthogonal to the first direction.

As shown in FIG. 3, the semiconductor device 300 may further include a third region (or may be referred to as a lower region or a buried region) 305 which has the second conductivity type; the third region 305 is configured within the drift layer 301 and is connected to the second region 304 in the second direction.

In this embodiment, a doping concentration of the first conductivity type in the second region 304 is lower than the doping concentration of the first conductivity type in the drift layer 301. For example, the doping concentration of the first conductivity type in the drift layer 301 is denoted by “n” and the doping concentration of the first conductivity type in the second region 304 is denoted by “n-”.

It should be appreciated that silicon or another material may be mainly used in the semiconductor device. For example, silicon carbide may be used in the drift layer 301, and a metal may be used in the electrode layer 302. However, it is not limited thereto, for example, semiconductor materials with a larger band gap may also be used. Next, silicon carbide may be used as an example of a material of the semiconductor device.

Furthermore, the semiconductor device may be one of the following apparatus or some components of the apparatus, e.g., Schottky diode, p-n diode, bipolar transistor, field effect transistor, metal oxide semiconductor transistor or junction gate field effect transistor. However, it is not limited thereto in this disclosure.

In an embodiment, the first conductivity type may be n-doping and the second conductivity type may be p-doping; however, it is not limited thereto in this disclosure.

In an embodiment, a plurality of the first regions may be configured within the drift layer and arranged along with the contact surface. Accordingly, one or more second regions and/or third regions may be configured for each of the first regions; however, it is not limited in this disclosure.

It should be appreciated that only one first region 303, one second region 304 and one third region 305 are illustrated as examples in FIG. 3. However, it is not limited thereto. For example, a plurality of regions may be configured within the drift layer 301. Furthermore, a neighboring region may be configured next to the first region 303. Some examples may be illustrated in the following embodiments.

In an embodiment, the semiconductor device may further include a fourth region having the first conductivity type; the fourth region is configured within the silicon carbide drift layer and is adjacent to the first region; the doping concentration of the first conductivity type in the fourth region is higher than the doping concentration of the first conductivity type in the silicon carbide drift layer.

FIG. 4 is a diagram which shows a schematic illustration of a cross-section of a semiconductor device 400 in accordance with an embodiment of the present disclosure. As shown in FIG. 4, the semiconductor device 400 includes a silicon carbide drift layer 401 which has a first conductivity type and an electrode layer 402 which is configured on the silicon carbide drift layer 401. A contact surface 4011 is formed in a first direction (such as X direction) between the silicon carbide drift layer 401 and the electrode layer 402.

As shown in FIG. 4, the semiconductor device 400 may further include a plurality of first regions 403; for example, three first regions are configured along the contact surface 4011 in FIG. 4. Each of the first regions 403 has a second conductivity type; the first region 403 is configured within the silicon carbide drift layer 401 and is contacted to the contact surface 4011.

As shown in FIG. 4, the semiconductor device 400 may further include a plurality of second regions 404; for example, three second regions are configured in FIG. 4. Each of the second regions 404 has the first conductivity type; the second region 404 is configured within the silicon carbide drift layer 401 and is connected to the first region 403 in a second direction (such as Y direction) which is basically orthogonal to the first direction.

As shown in FIG. 4, the semiconductor device 400 may further include a plurality of third regions 405; for example, three third regions are configured in FIG. 4. Each of the third regions 405 has the second conductivity type; the third region 405 is configured within the silicon carbide drift layer 401 and is connected to the second region 404 in the second direction.

As shown in FIG. 4, the semiconductor device 400 may further include a plurality of fourth region (or may be referred to as a neighboring region) 406. Each of the fourth regions 406 has the first conductivity type; the fourth region 406 is configured within the silicon carbide drift layer 401 and is adjacent to the first region 403.

As shown in FIG. 4, the semiconductor device 400 may further include a silicon carbide substrate 407 which has the first conductivity type; the silicon carbide drift layer 401 is configured on the silicon carbide substrate 407.

In this embodiment, the doping concentration of the first conductivity type in the fourth region 406 is higher than the doping concentration of the first conductivity type in the silicon carbide drift layer 401. The doping concentration of the first conductivity type in the second region 404 is lower than the doping concentration of the first conductivity type in the silicon carbide drift layer 401. The doping concentration of the first conductivity type in the silicon carbide drift layer 401 is lower than the doping concentration of the first conductivity type in the silicon carbide substrate 407.

For example, the doping concentration of the first conductivity type in the silicon carbide drift layer 401 is denoted by “n”. The doping concentration of the first conductivity type in the fourth region 406 is denoted by “n+”. The doping concentration of the first conductivity type in the second region 404 is denoted by “n-”. The doping concentration of the first conductivity type in the silicon carbide substrate 407 is denoted by “n++”.

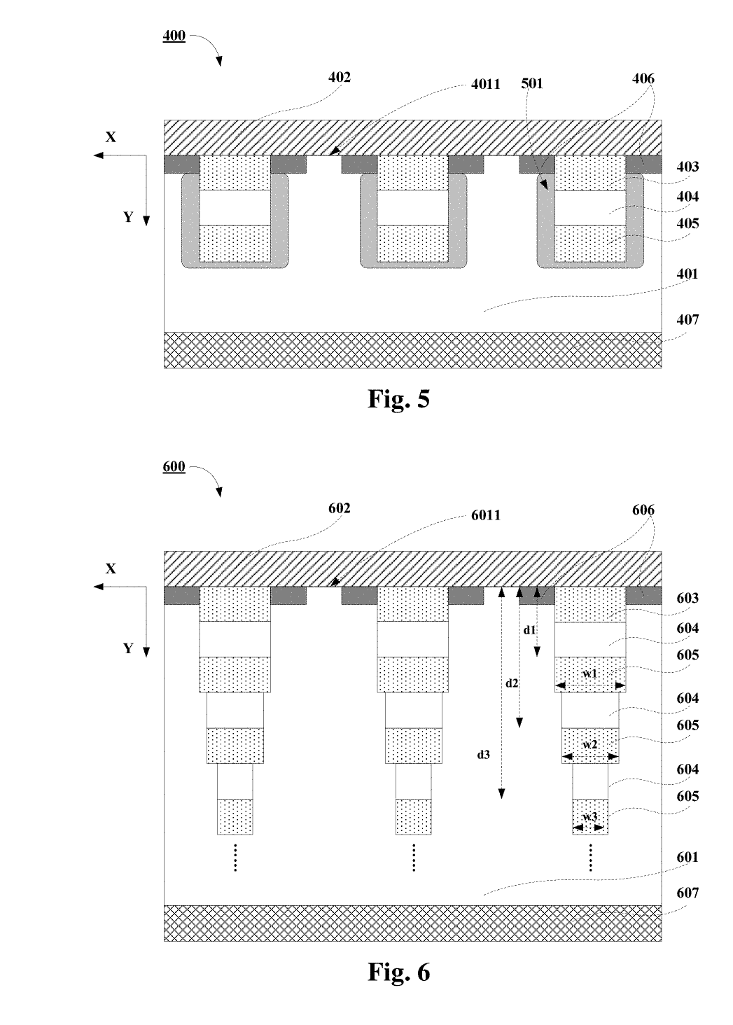

FIG. 5 is a diagram which shows an example of forming a depletion layer in accordance with an embodiment of the present disclosure. As shown in FIG. 5, a depletion layer 501 is formed when a backward biasing voltage is applied and the depletion layer 501 is extended to the second region 404, since the doping concentration of the first conductivity type in the second region 404 is lower than the doping concentration of the first conductivity type in the silicon carbide drift layer 401.

Furthermore, the depletion layer 501 may be extended and connected to the third region 405 when the backward biasing voltage is applied. Therefore, an electric field of the first region 403 may be reduced; a breakdown behavior and a long-term reliability of the semiconductor device 400 may be further improved.

In an embodiment, corresponding to each of the first regions, a plurality of the second regions and/or the third regions may be configured within the silicon carbide drift layer.

FIG. 6 is a diagram which shows a schematic illustration of a cross-section of a semiconductor device 600 in accordance with an embodiment of the present disclosure. As shown in FIG. 6, the semiconductor device 600 includes a silicon carbide drift layer 601 which has a first conductivity type and an electrode layer 602 which is configured on the silicon carbide drift layer 601. A contact surface 6011 is formed in a first direction (such as X direction) between the silicon carbide drift layer 601 and the electrode layer 602.

As shown in FIG. 6, The semiconductor device 600 may further include a plurality of first regions 603, for example, three first regions are configured along the contact surface 6011 in FIG. 6. Each of the first regions 603 has a second conductivity type; the first region 603 is configured within the silicon carbide drift layer 601 and is contacted to the contact surface 6011.

As shown in FIG. 6, the semiconductor device 600 may further include a plurality of the second regions 604, for example, nine second regions are configured in FIG. 6. For each of the first regions 603, a plurality of the second regions 604 are configured; for example, one first region is corresponding to three second regions.

The second region 604 has the first conductivity type. The second region 604 is configured within the silicon carbide drift layer 601 and is connected to the first region 603 in a second direction (such as Y direction) which is basically orthogonal to the first direction.

As shown in FIG. 6, the semiconductor device 600 may further include a plurality of third regions 605, for example, nine third regions are configured in FIG. 6. For each of the first region 603, a plurality of the third regions 605 are configured; for example, one first region is corresponding to three third regions.

The third region 605 has the second conductivity type. The third region 605 is configured within the silicon carbide drift layer 601 and is connected to the second region 604 in the second direction.

As shown in FIG. 6, the semiconductor device 600 may further include a plurality of fourth regions 606. The fourth regions 606 has the first conductivity type; the fourth region 606 is configured within the silicon carbide drift layer 601 and is adjacent to the first region 603.

As shown in FIG. 6, the semiconductor device 600 may further include a silicon carbide substrate 607 which has the first conductivity type; the silicon carbide drift layer 601 is configured on the silicon carbide substrate 607.

As shown in FIG. 6, as distances from the contact surface 6011 in the second direction (such as Y direction) are increased, widths of the plurality of the third regions 605 may be gradually (or stepwise) decreased.

That is, the farther the distance from the contact surface 6011 is, the shorter the width of the third region 605 is; the closer the distance to the contact surface 6011 is, the longer the width of the third region 605 is.

For example, as shown in FIG. 6, distances between the third regions 605 and the contact surface 6011 are d1, d2, d3 . . . , and d1<d2<d3< . . . ; the widths of the third regions 605 in the X direction are w1, w2, w3, then w1>w2>w3> . . . .

As shown in FIG. 6, as distances from the contact surface 6011 in the second direction (such as Y direction) are increased, widths of the plurality of the second regions 604 may also be gradually (or stepwise) decreased.

That is, the farther the distance from the contact surface 6011 is, the shorter the width of the second region 604 is; the closer the distance to the contact surface 6011 is, the longer the width of the second region 604 is.

Therefore, an electric field of the first region 603 may further be reduced; a breakdown behavior and a long-term reliability of the semiconductor device 600 may further be further improved.

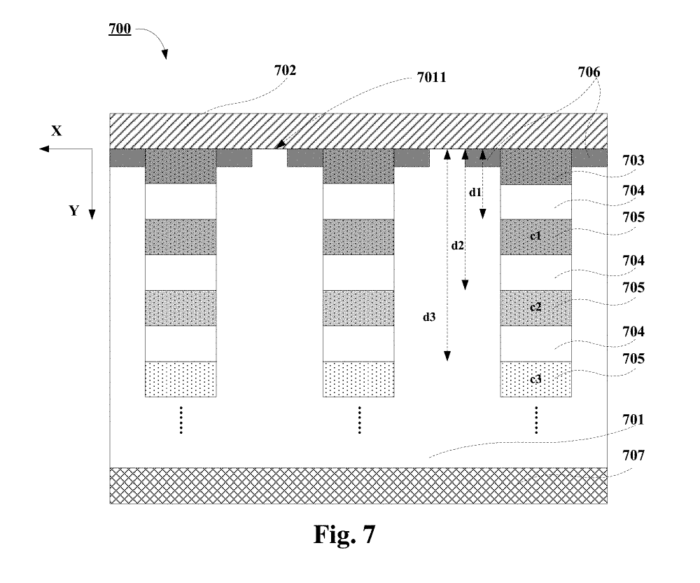

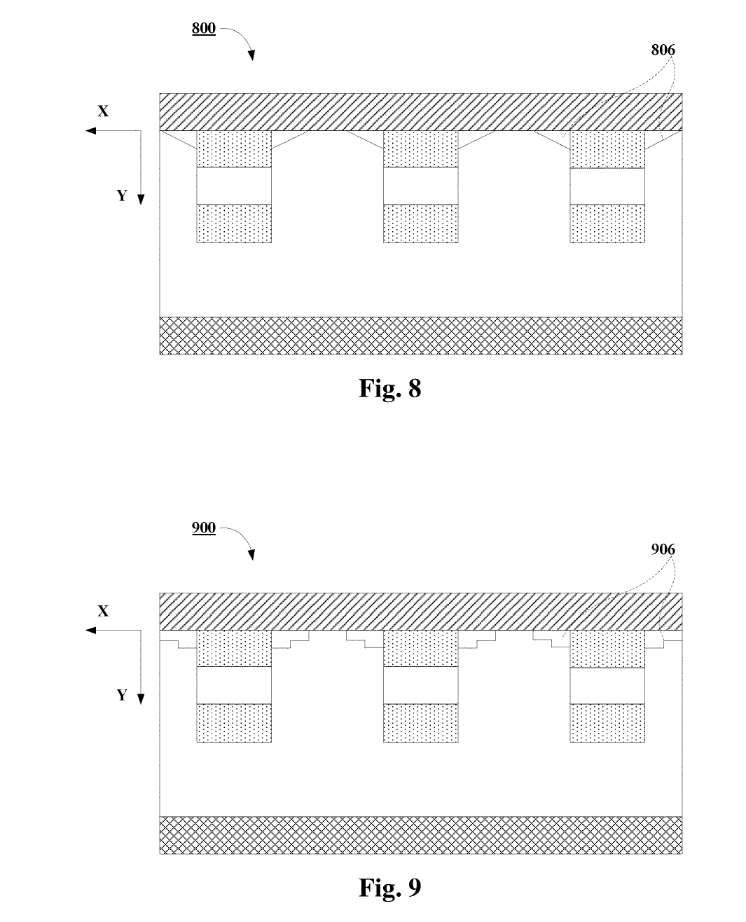

FIG. 7 is a diagram which shows a schematic illustration of a cross-section of a semiconductor device 700 in accordance with an embodiment of the present disclosure. As shown in FIG. 7, the semiconductor device 700 includes a silicon carbide drift layer 701 which has a first conductivity type and an electrode layer 702 which is configured on the silicon carbide drift layer 701. A contact surface 7011 is formed in a first direction (such as X direction) between the silicon carbide drift layer 701 and the electrode layer 702.

As shown in FIG. 7, The semiconductor device 700 may further include a plurality of first regions 703; for example, three first regions are configured along the contact surface 7011 in FIG. 7. Each of the first regions 703 has a second conductivity type; the first region 703 is configured within the silicon carbide drift layer 701 and is contacted to the contact surface 7011.

As shown in FIG. 7, the semiconductor device 700 may further include a plurality of second regions 704, for example, nine second regions are configured in FIG. 7. For each of the first regions 703, a plurality of the second regions 704 are configured; for example, one first region is corresponding to three second regions.

The second region 704 has the first conductivity type. The second region 704 is configured within the silicon carbide drift layer 701 and is connected to the first region 703 in a second direction (such as Y direction) which is basically orthogonal to the first direction.

As shown in FIG. 7, the semiconductor device 700 may further include a plurality of third regions 705, for example, nine third regions are configured in FIG. 7. For each of the first region 703, a plurality of the third regions 705 are configured; for example, one first region is corresponding to three third regions.

The third region 705 has the second conductivity type. The third region 705 is configured within the silicon carbide drift layer 701 and is connected to the second region 704 in the second direction.

As shown in FIG. 7, the semiconductor device 700 may further include a plurality of fourth regions 706. The fourth regions 706 has the first conductivity type; the fourth region 706 is configured within the silicon carbide drift layer 701 and is adjacent to the first region 703.

As shown in FIG. 7, the semiconductor device 700 may further include a silicon carbide substrate 707 which has the first conductivity type; the silicon carbide drift layer 701 is configured on the silicon carbide substrate 707.

As shown in FIG. 7, as distances from the contact surface 7011 in the second direction (such as Y direction) are increased, the doping concentration of the second conductivity type in the third regions 705 may be gradually (or stepwise) decreased.

That is, the farther the distance from the contact surface 7011 is, the lower the doping concentration of the second conductivity type in the third region 705 is; the closer the distance to the contact surface 7011 is, the higher the doping concentration of the second conductivity type in the third region 705 is.

For example, as shown in FIG. 7, distances between the third regions 705 and the contact surface 7011 are d1, d2, d3 . . . , and d1<d2<d3<; the doping concentration of the second conductivity type in the third regions 705 are c1, c2, c3 . . . , then c1>c2>c3> . . . .

As shown in FIG. 7, as distances from the contact surface 7011 in the second direction (such as Y direction) are increased, the doping concentration of the first conductivity type in the second regions 704 may be gradually (or stepwise) decreased.

That is, the farther the distance from the contact surface 7011 is, the lower the doping concentration of the first conductivity type in the second region 704 is; the closer the distance to the contact surface 7011 is, the higher the doping concentration of the first conductivity type in the second region 704 is.

Therefore, an electric field of the first region 703 may further be reduced; a breakdown behavior and a long-term reliability of the semiconductor device 700 may further be further improved.

As shown in FIG. 6 and FIG. 7, the second region and the third region may be alternatively configured along the second direction; for example, the second region, then the third region, then the second region, then the third region, are configured in turn in Y direction. However, it is not limited thereto in this disclosure. For example, for a first region, two second regions may be directly connected, and/or, two third regions may be directly connected.

It should be appreciated that FIG. 6 and FIG. 7 are only examples, but it is not limited thereto. For example, the second regions and the third regions may be configured independently. For example, the doping concentration of the second conductivity type in the third regions may be stepwise decreased, while the doping concentration of the first conductivity type in the second regions may be the same.

Furthermore, the structure of the semiconductor device 600 in FIG. 6 may be combined with the structure of the semiconductor device 700 in FIG. 7; but it is not limited thereto.

In an embodiment, a surface of the fourth region towards (or facing) the silicon carbide drift layer may be configured to enlarge a contact area which is formed between the fourth region and the silicon carbide drift layer.

For example, a cross-section of the fourth region may include one of the following shapes: a triangle shape, a ladder (or stepped) shape and a curved shape. However, it is not limited thereto in this disclosure.

FIG. 8 is a diagram which shows a schematic illustration of a cross-section of a semiconductor device 800 in accordance with an embodiment of the present disclosure. As shown in FIG. 8, the cross-section of the fourth region 806 may be a triangle shape.

FIG. 9 is a diagram which shows a schematic illustration of a cross-section of a semiconductor device 900 in accordance with an embodiment of the present disclosure. As shown in FIG. 9, the cross-section of the fourth region 906 may be a ladder shape.

For the sake of simplicity, some marks in the FIG. 8 and FIG. 9 are omitted.

Therefore, an electric field of the first region may further be reduced; a breakdown behavior and a long-term reliability of the semiconductor device may further be further improved.

It should be appreciated that FIG. 8 and FIG. 9 are only examples, but it is not limited thereto. For example, the structure of the semiconductor devices in FIGS. 3-7 may be combined with the structure of the semiconductor devices in FIGS. 8-9.

It is to be understood that, the above examples or embodiments are discussed for illustration, rather than limitation. Those skilled in the art would appreciate that there may be many other embodiments or examples within the scope of the present disclosure.

As can be seen from the above embodiments, a middle region (the second region) having the first conductivity type is configured between the upper region (the first region) and the lower region (the third region), and a doping concentration of the first conductivity type in the second region is lower than the doping concentration of the first conductivity type in the drift layer.

Therefore, the depletion layer may be extended and connected to the lower region when the backward biasing voltage is applied. An electric field of the upper region may be reduced; a breakdown behavior and a long-term reliability of the semiconductor device may be further improved.

### A Second Aspect of Embodiments

A method for manufacturing a semiconductor device is provided in these embodiments. The semiconductor device is illustrated in the first aspect of embodiments, and the same contents as those in the first aspect of embodiments are omitted.

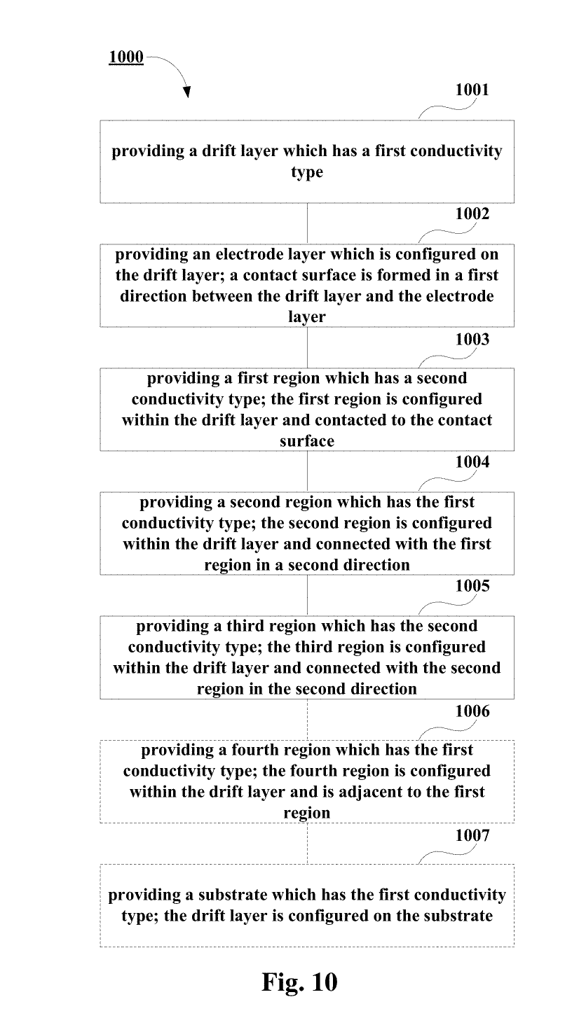

FIG. 10 is a diagram which shows a method for manufacturing a semiconductor device in accordance with an embodiment of the present disclosure. As shown in FIG. 10, the method 1000 includes:

Block 1001, providing a drift layer which has a first conductivity type.

Block 1002, providing an electrode layer which is configured on the drift layer; a contact surface is formed in a first direction between the drift layer and the electrode layer.

Block 1003, providing a first region which has a second conductivity type; the first region is configured within the drift layer and contacted to the contact surface.

Block 1004, providing a second region which has the first conductivity type; the second region is configured within the drift layer and connected to the first region in a second direction which is basically orthogonal to the first direction; and

Block 1005, providing a third region which has the second conductivity type; the third region is configured within the drift layer and connected to the second region in the second direction.

In this disclosure, a doping concentration of the first conductivity type in the second region is lower than the doping concentration of the first conductivity type in the drift layer.

As shown in FIG. 10, the method 1000 may further include:

Block 1006, providing a fourth region which has the first conductivity type; the fourth region is configured within the drift layer and is adjacent to the first region. The doping concentration of the first conductivity type in the fourth region is higher than the doping concentration of the first conductivity type in the drift layer.

As shown in FIG. 10, the method 1000 may further include:

Block 1007, providing a substrate which has the first conductivity type; the drift layer is configured on the substrate. The doping concentration of the first conductivity type in the drift layer is lower than the doping concentration of the first conductivity type in the substrate.

It should be appreciated that FIG. 10 is only an example of the disclosure, but it is not limited thereto. For example, the order of operations at blocks may be adjusted and/or some blocks may be omitted. Moreover, some blocks not shown in FIG. 10 may be added.

In an embodiment, corresponding to the first region, a plurality of the second regions and/or the third regions may be configured within the drift layer.

In an embodiment, as distances from the contact surface in the second direction are increased, widths of the plurality of the second regions and/or the third regions may be gradually decreased.

In an embodiment, as distances from the contact surface in the second direction are increased, the doping concentration of the first conductivity type in the second regions and/or the doping concentration of the second conductivity type in the third regions may be gradually decreased.

In an embodiment, a cross-section of the fourth region may include one of the following shapes: a triangle shape, a ladder shape and a curved shape.

As can be seen from the above embodiments, a middle region (the second region) having the first conductivity type is configured between the upper region (the first region) and the lower region (the third region), and a doping concentration of the first conductivity type in the second region is lower than the doping concentration of the first conductivity type in the drift layer.

Therefore, the depletion layer may be extended and connected to the lower region when the backward biasing voltage is applied. An electric field of the upper region may be reduced; a breakdown behavior and a long-term reliability of the semiconductor device may be further improved.

Further, it is expected that one of ordinary skill, notwithstanding possibly significant effort and many design choices motivated by, for example, available time, current technology, and economic considerations, when guided by the concepts and principles disclosed herein will be readily capable of generating such software instructions and programs and integrated circuits (ICs) with minimal experimentation.

Generally, various embodiments of the present disclosure may be implemented in hardware or special purpose circuits, software, logic or any combination thereof. Some aspects may be implemented in hardware, while other aspects may be implemented in firmware or software which may be executed by a controller, microprocessor or other computing device.

While various aspects of embodiments of the present disclosure are illustrated and described as block diagrams, flowcharts, or using some other pictorial representation, it will be appreciated that the blocks, apparatus, systems, techniques or methods described herein may be implemented in, as non-limiting examples, hardware, software, firmware, special purpose circuits or logic, general purpose hardware or controller or other computing devices, or some combination thereof.

Further, while operations are depicted in a particular order, this should not be understood as requiring that such operations be performed in the particular order shown or in sequential order, or that all illustrated operations be performed, to achieve desirable results. In certain circumstances, multitasking and parallel processing may be advantageous.

Likewise, while several specific implementation details are contained in the above discussions, these should not be construed as limitations on the scope of the present disclosure, but rather as descriptions of features that may be specific to particular embodiments. Certain features that are described in the context of separate embodiments may also be implemented in combination in a single embodiment. Conversely, various features that are described in the context of a single embodiment may also be implemented in multiple embodiments separately or in any suitable sub-combination.

Although the present disclosure has been described in language specific to structural features and/or methodological acts, it is to be understood that the present disclosure defined in the appended claims is not necessarily limited to the specific features or acts described above. Rather, the specific features and acts described above are disclosed as example forms of implementing the claims.

1. A semiconductor device, comprising:
a drift layer having a first conductivity type;
an electrode layer configured on the drift layer; wherein a contact surface is formed in a first direction between the drift layer and the electrode layer;
a first region having a second conductivity type; the first region is configured within the drift layer and contacted to the contact surface;
a second region having the first conductivity type; wherein the second region is configured within the drift layer in such a way that a side surface of the second region is contiguous to the drift layer, and connected to the first region in a second direction which is orthogonal to the first direction; a doping concentration of the first conductivity type in the second region is lower than the doping concentration of the first conductivity type in the drift layer; and
a third region having the second conductivity type; wherein the third region is configured under the second region within the drift layer and connected to the second region in the second direction.

2. The semiconductor device according to the claim 1, wherein the semiconductor device further comprises:
a fourth region having the first conductivity type; wherein the fourth region is configured within the drift layer and is adjacent to the first region; the doping concentration of the first conductivity type in the fourth region is higher than the doping concentration of the first conductivity type in the drift layer.

3. The semiconductor device according to the claim 1, wherein the semiconductor device further comprises:
a substrate having the first conductivity type; wherein the drift layer is configured on the substrate; the doping concentration of the first conductivity type in the drift layer is lower than the doping concentration of the first conductivity type in the substrate.

4. The semiconductor device according to the claim 1, wherein the first conductivity type is n-doping and the second conductivity type is p-doping.

5. The semiconductor device according to the claim 1, wherein a plurality of the first regions are configured within the drift layer and arranged along the contact surface.

6. The semiconductor device according to the claim 1, wherein corresponding to the first region, a plurality of the second regions and/or the third regions are configured within the drift layer.

7. The semiconductor device according to the claim 6, wherein as distances from the contact surface in the second direction are increased, widths of the second regions and/or the third regions are decreased.

8. The semiconductor device according to the claim 6, wherein as distances from the contact surface in the second direction are increased, the doping concentration of the first conductivity type in the second regions and/or the doping concentration of the second conductivity type in the third regions is decreased.

9. The semiconductor device according to the claim 6, wherein the second region and the third region are alternatively configured along the second direction.

10. The semiconductor device according to the claim 2, wherein a surface of the fourth region towards the drift layer is configured to enlarge a contact area which is formed between the fourth region and the drift layer.

11. The semiconductor device according to the claim 2, wherein a cross-section of the fourth region comprises one of the following shapes: a triangle shape, a ladder shape and a curved shape.

12. A method for manufacturing a semiconductor device, comprising:
providing a drift layer which has a first conductivity type;
providing an electrode layer which is configured on the drift layer; wherein a contact surface is formed in a first direction between the drift layer and the electrode layer;
providing a first region which has a second conductivity type; the first region is configured within the drift layer and contacted to the contact surface;
providing a second region which has the first conductivity type; the second region is configured within the drift layer in such a way that a side surface of the second region is contiguous to the drift layer, and connected to the first region in a second direction which is orthogonal to the first direction; a doping concentration of the first conductivity type in the second region is lower than the doping concentration of the first conductivity type in the drift layer; and
providing a third region which has the second conductivity type; wherein the third region is configured within the drift layer and connected to the second region in the second.

13. The method according to the claim 12, wherein the method further comprises:
providing a fourth region which has the first conductivity type; wherein the fourth region is configured within the drift layer and is adjacent to the first region; the doping concentration of the first conductivity type in the fourth region is higher than the doping concentration of the first conductivity type in the drift layer.

14. The method according to the claim 12, wherein the method further comprises:
providing a substrate which has the first conductivity type; wherein the drift layer is configured on the substrate and the doping concentration of the first conductivity type in the drift layer is lower than the doping concentration of the first conductivity type in the substrate.

15. The method according to the claim 12, wherein a plurality of the first regions are configured within the drift layer and arranged along the contact surface.

16. The method according to the claim 12, wherein corresponding to the first region, a plurality of the second regions and/or the third regions are configured within the drift layer.

17. The method according to the claim 16, wherein as distances from the contact surface in the second direction are increased, widths of the second regions and/or the third regions are decreased.

18. The method according to the claim 16, wherein as distances from the contact surface in the second direction are increased, the doping concentration of the first conductivity type in the second regions and/or the doping concentration of the second conductivity type in the third regions is decreased.

19. The method according to the claim 13, wherein a surface of the fourth region towards the drift layer is configured to enlarge a contact area which is formed between the fourth region and the drift layer.

20. The method according to the claim 13, wherein a cross-section of the fourth region comprises one of the following shapes: a triangle shape, a ladder shape and a curved shape.
